(19) United States
(12) Patent Application Publication
(10) Pub. No.: US 2021/0091592 A1
(43) Pub. Date: Mar. 25, 2021

(54) Energy Charging Assembly

(71) Applicants: Christopher Humble, Webster, TX (US); Shajuana Humble, Webster, TX (US)

(72) Inventors: Christopher Humble, Webster, TX (US); Shajuana Humble, Webster, TX (US)

(21) Appl. No.: 16/575,616

(22) Filed: Sep. 19, 2019

(51) Int. Cl. H02J 7/35; H02J 7/02

(52) U.S. Cl. CPC H02J 7/35; H02J 2007/0096; H02J 7/025

(57) ABSTRACT

An energy charging assembly includes a housing for receiving a personal electronic device. A kinetic charger is coupled to the housing and a solar charger is coupled to the housing. An electromagnetic charger is coupled to the housing and a thermal charger is coupled to the housing. A radio charger is coupled to the housing. A power supply is coupled to the housing to store electrical energy produced by each of the kinetic charger, the solar charger, the electromagnetic charger, the thermal charger and the radio charger. A transmission unit is coupled to the housing and the transmission unit is in electrical communication with the power supply. The transmission unit is placed in electrical communication with the personal electronic device when the personal electronic device is inserted into the housing for charging the personal electronic device.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to charging devices and more particularly pertains to a new charging device for harnessing free energy for charging personal electronic devices.

### (2) Description of Related Art Including Information Disclosed Under 37 CFR 1.97 and 1.98

The prior art relates to charging devices.

### BRIEF SUMMARY OF THE INVENTION

An embodiment of the disclosure meets the needs presented above by generally comprising a housing for receiving a personal electronic device. A kinetic charger is coupled to the housing and a solar charger is coupled to the housing. An electromagnetic charger is coupled to the housing and a thermal charger is coupled to the housing. A radio charger is coupled to the housing. A power supply is coupled to the housing to store electrical energy produced by each of the kinetic charger, the solar charger, the electromagnetic charger, the thermal charger and the radio charger. A transmission unit is coupled to the housing and the transmission unit is in electrical communication with the power supply. The transmission unit is placed in electrical communication with the personal electronic device when the personal electronic device is inserted into the housing for charging the personal electronic device.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is an exploded perspective view of a free energy charging assembly according to an embodiment of the disclosure.

FIG. 2 is a front view of a housing of an embodiment of the disclosure.

FIG. 3 is a perspective in-use view of an embodiment of the disclosure.

FIG. 4 is a schematic view of an embodiment of the disclosure.

### DETAILED DESCRIPTION OF THE INVENTION

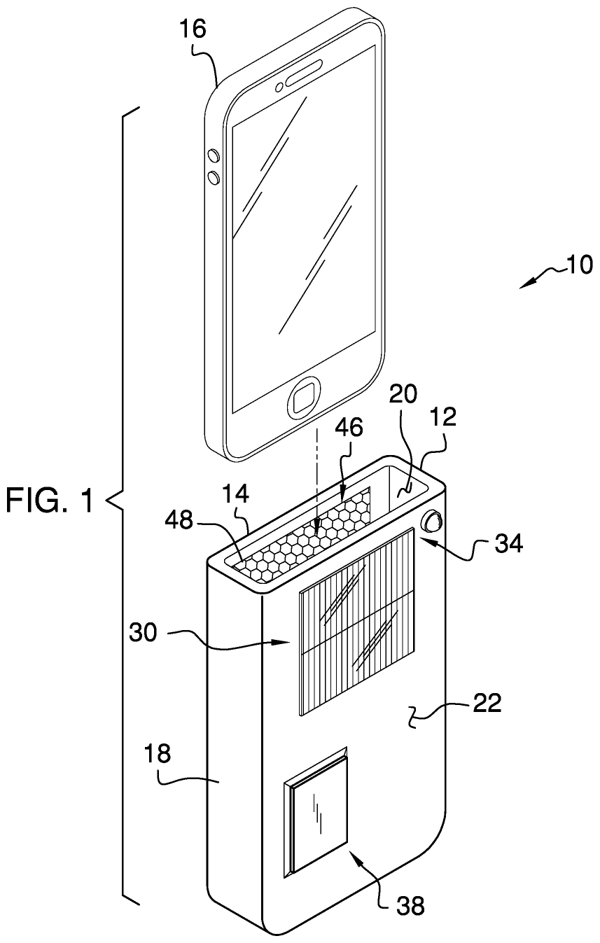

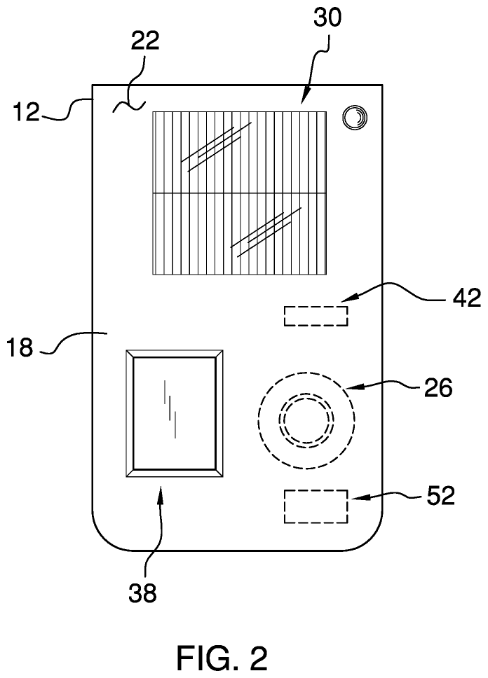

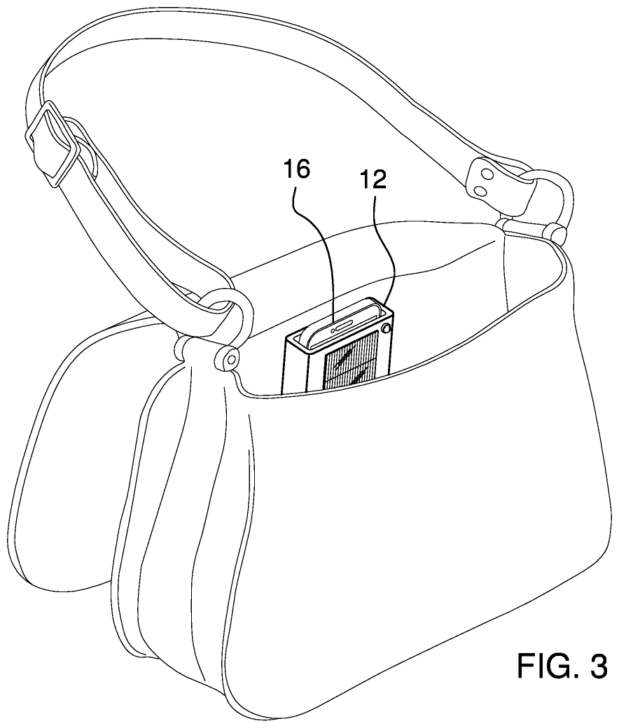

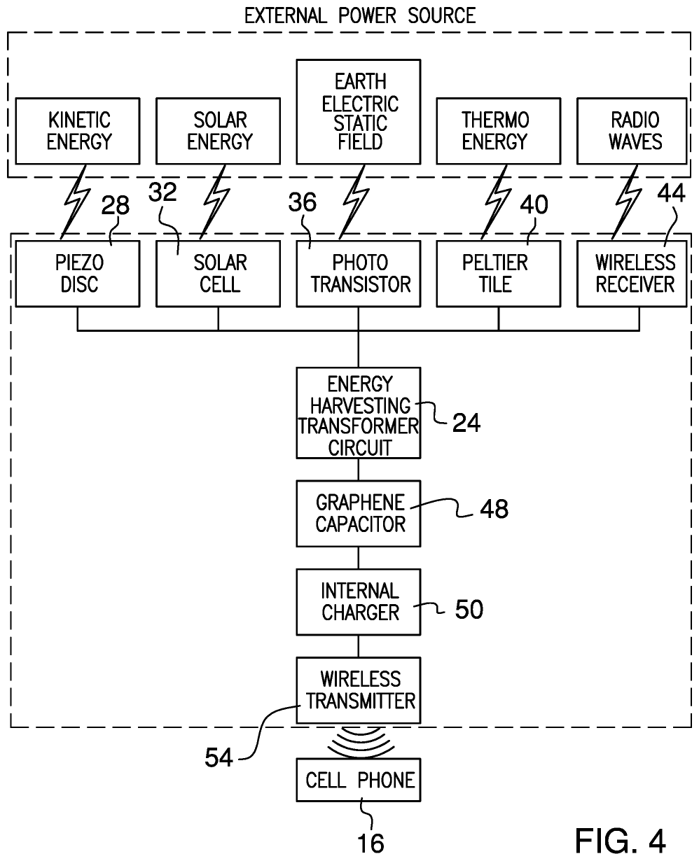

With reference now to the drawings, and in particular to FIGS. 1 through 4 thereof, a new charging device embodying the principles and concepts of an embodiment of the disclosure and generally designated by the reference numeral 10 will be described.

As best illustrated in FIGS. 1 through 4, the energy charging assembly 10 generally comprises a housing 12 that has a top end 14 which is open for receiving a personal electronic device 16. The personal electronic device 16 may comprise a smart phone or other electronic device that has wireless charging capabilities. The housing 12 has an outer wall 18, and the outer wall 18 has an inner surface 20 and an outer surface 22. The housing 12 is positionable in a bag that can be carried by a user or carried in any other manner by the user.

A control circuit 24 is provided and the control circuit 24 is coupled to the housing 12. The control circuit 24 may include a transformer and other electronic components commonly associated with electrical chargers. A kinetic charger 26 is coupled to the housing 12. The kinetic charger 26 produces an electrical charge from repetitive motion. In this way the kinetic charger 26 can harness energy from the user walking. The kinetic charger 26 comprises a piezo disk 28 that is positioned on the inner surface 20 of the outer wall 18 of the housing 12. The piezo disk 28 is electrically coupled to the control circuit 24.

A solar charger 30 is coupled to the housing 12. The solar charger 30 produces an electrical charge from sunlight to harness energy from the sun. The solar charger 30 comprises a solar panel 32 that is positioned on the outer surface 22 of the outer wall 18 of the housing 12. The solar panel 32 is electrically coupled to the control circuit 24.

An electromagnetic charger 34 is coupled to the housing 12. The electromagnetic charger 34 produces an electrical charge from the Earth's static electrical field. In this way the electromagnetic charger 34 can harness energy from Earth's static electrical field. The electromagnetic charger 34 comprises a phototransistor 36 that is positioned on the outer surface 22 of the outer wall 18 of the housing 12. The phototransistor 36 is electrically coupled to the control circuit 24. Additionally, the phototransistor 36 may comprise a phototransistor that operates in the frequency range of the electromagnetic spectrum associated with the Earth's magnetic field.

A thermal charger 38 is coupled to the housing 12. The thermal charger 38 is in thermal communication with ambient air with respect to the housing 12. Additionally, the thermal charger 38 produces an electrical charge from heat transmission. In this way the thermal charger 38 can harness energy from the heat of ambient air. The thermal charger 38 comprises a peltier tile 40 that is positioned on the outer surface 22 of the outer wall 18 of the housing 12. The peltier tile 40 is electrically coupled to the control circuit 24.

A radio charger 42 is coupled to the housing 12. The radio charger 42 produces an electrical charge from radio frequency electromagnetic radiation. In this way the radio charger 42 can harness energy from radio frequency transmissions that are constantly being broadcast in a typical urban area. The radio charger 42 comprises a receiver 44 that is positioned on the outer wall 18 of the housing 12. The receiver 44 is electrically coupled to the control circuit 24 and the receiver 44 may be a radio frequency receiver or the like.

A power supply 46 is coupled to the housing 12. The power supply 46 is in electrical communication with each of the kinetic charger 26, the solar charger 30, the electromagnetic charger 34, the thermal charger 38 and the radio charger 42. Moreover, the power supply 46 stores electrical energy produced by each of the kinetic charger 26, the solar charger 30, the electromagnetic charger 34, the thermal charger 38 and the radio charger 42.

The power supply 46 comprises a graphene supercapacitor 48 that is positioned on the inner surface 20 of the outer wall 18 of the housing 12. The graphene supercapacitor 48 is electrically coupled to the control circuit 24. The power supply 46 additionally includes at least one battery 50 that is coupled to the outer wall 18 of the housing 12. The at least one battery 50 is electrically coupled to the control circuit 24.

A transmission unit 52 is coupled to the housing 12 and the transmission unit 52 is in electrical communication with the power supply 46. The transmission unit 52 is placed in electrical communication with the personal electronic device 16 when the personal electronic device 16 is inserted into the housing 12. In this way the transmission unit 52 can charge the personal electronic device 16.

The transmission unit 52 comprises a transmitter 54 that is coupled to the outer wall 18 of the housing 12. The transmitter 54 is electrically coupled to the control circuit 24. Additionally, the transmitter 54 is in wireless electrical communication with the personal electronic device 16 when the personal electronic device 16 is positioned in the housing 12. The transmitter 54 broadcasts an electrical charge to the personal electronic device 16 for charging the personal electronic device 16. The transmitter 54 may comprise a radio frequency transmitter that is capable of broadcasting an electrical charge on a carrier wave.

In use, the housing 12 is carried in purse, a pocket in the user's clothes or in any other chosen manner. The personal electronic device 16 is inserted into the housing 12 for the purposes of charging the personal electronic device 16. The transmitter 54 wirelessly charges the personal electronic device 16 when the personal electronic device 16 in the housing 12. The graphene supercapacitor 48 facilitates the personal electronic device 16 to be rapidly charged, while the at least one battery 50 facilitates a slower rate of charge over a longer period of time. In this way the power supply 46 enables the user to reap the benefits of capacitance charging and battery 50 charging.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. An energy charging assembly being configured to harness solar energy, kinetic energy, radio energy and the earth's magnetic field for charging personal electronic device, said assembly comprising:
a housing having a top end being open for receiving a personal electronic device;
a kinetic charger being coupled to said housing, said kinetic charger producing an electrical charge from repetitive motion wherein said kinetic charger is configured to harness energy from the user walking;
a solar charger being coupled to said housing, said solar charger producing an electrical charge from sunlight wherein said solar charger is configured to harness energy from the sun;
an electromagnetic charger being coupled to said housing, said electromagnetic charger producing an electrical charge from the Earth's static electrical field wherein said electromagnetic charger is configured to harness energy from Earth's static electrical field;
a thermal charger being coupled to said housing, said thermal charger being in thermal communication with ambient air with respect to said housing, said thermal charger producing an electrical charge from heat transmission wherein said thermal charger is configured to harness energy from the heat of ambient air;
a radio charger being coupled to said housing, said radio charger producing an electrical charge from radio frequency electromagnetic radiation wherein said radio charger is configured to harness energy from radio frequency transmissions;
a power supply being coupled to said housing, being in electrical communication with each of said kinetic charger, said solar charger, said electromagnetic charger, said thermal charger and said radio charger, said power supply storing electrical energy produced by each of said kinetic charger, said solar charger, said electromagnetic charger, said thermal charger and said radio charger; and
a transmission unit being coupled to said housing, said transmission unit being in electrical communication with said power supply, said transmission unit being placed in electrical communication with the personal electronic device when the personal electronic device is inserted into said housing for charging the personal electronic device.

2. The assembly according to claim 1, wherein:
said housing has an outer wall, said outer wall having an inner surface and an outer surface, said housing being positionable in a bag being carried by a user; and
said assembly includes a control circuit being coupled to said housing.

3. The assembly according to claim 2, wherein said kinetic charger comprises a piezo disk being positioned on said inner surface of said outer wall of said housing, said piezo disk being electrically coupled to said control circuit.

4. The assembly according to claim 2, further comprising said solar charger comprises a solar panel being positioned on said outer surface of said outer wall of said housing, said solar panel being electrically coupled to said control circuit.

5. The assembly according to claim 2, wherein said electromagnetic charger comprises a photo transistor being positioned on said outer surface of said outer wall of said housing, said photo transistor being electrically coupled to said control circuit.

6. The assembly according to claim 2, wherein said thermal charger comprises a peltier tile being positioned on said outer surface of said outer wall of said housing, said peltier tile being electrically coupled to said control circuit.

7. The assembly according to claim 2, wherein said radio charger comprises a receiver being positioned on said outer wall of said housing, said receiver being electrically coupled to said control circuit.

8. The assembly according to claim 2, wherein said power supply comprises:
a graphene supercapacitor being positioned on said inner surface of said outer wall of said housing, said graphene supercapacitor being electrically coupled to said control circuit; and
at least one battery being coupled to said outer wall of said housing, said at least one battery being electrically coupled to said control circuit.

9. The assembly according to claim 8, wherein said transmission unit comprises a transmitter being coupled to said outer wall of said housing, said transmitter being electrically coupled to said control circuit, said transmitter being in wireless electrical communication with the personal electronic device when the personal electronic device is positioned in said housing, said transmitter broadcasting an electrical charge to the personal electronic device for charging the personal electronic device.

10. An energy charging assembly being configured to harness solar energy, kinetic energy, radio energy and the earth's magnetic field for charging personal electronic device, said assembly comprising:
a housing having a top end being open for receiving a personal electronic device, said housing having an outer wall, said outer wall having an inner surface and an outer surface, said housing being positionable in a bag being carried by a user;
a control circuit being coupled to said housing;
a kinetic charger being coupled to said housing, said kinetic charger producing an electrical charge from repetitive motion wherein said kinetic charger is configured to harness energy from the user walking, said kinetic charger comprising a piezo disk being positioned on said inner surface of said outer wall of said housing, said piezo disk being electrically coupled to said control circuit;
a solar charger being coupled to said housing, said solar charger producing an electrical charge from sunlight wherein said solar charger is configured to harness energy from the sun, said solar charger comprising a solar panel being positioned on said outer surface of said outer wall of said housing, said solar panel being electrically coupled to said control circuit;
an electromagnetic charger being coupled to said housing, said electromagnetic charger producing an electrical charge from the Earth's static electrical field wherein said electromagnetic charger is configured to harness energy from Earth's static electrical field, said electromagnetic charger comprising a photo transistor being positioned on said outer surface of said outer wall of said housing, said photo transistor being electrically coupled to said control circuit;
a thermal charger being coupled to said housing, said thermal charger being in thermal communication with ambient air with respect to said housing, said thermal charger producing an electrical charge from heat transmission wherein said thermal charger is configured to harness energy from the heat of ambient air, said thermal charger comprising a peltier tile being positioned on said outer surface of said outer wall of said housing, said peltier tile being electrically coupled to said control circuit;
a radio charger being coupled to said housing, said radio charger producing an electrical charge from radio frequency electromagnetic radiation wherein said radio charger is configured to harness energy from radio frequency transmissions, said radio charger comprising a receiver being positioned on said outer wall of said housing, said receiver being electrically coupled to said control circuit;
a power supply being coupled to said housing, being in electrical communication with each of said kinetic charger, said solar charger, said electromagnetic charger, said thermal charger and said radio charger, said power supply storing electrical energy produced by each of said kinetic charger, said solar charger, said electromagnetic charger, said thermal charger and said radio charger, said power supply comprising:
a graphene supercapacitor being positioned on said inner surface of said outer wall of said housing, said graphene supercapacitor being electrically coupled to said control circuit; and
at least one battery being coupled to said outer wall of said housing, said at least one battery being electrically coupled to said control circuit; and
a transmission unit being coupled to said housing, said transmission unit being in electrical communication with said power supply, said transmission unit being placed in electrical communication with the personal electronic device when the personal electronic device is inserted into said housing for charging the personal electronic device, said transmission unit comprising a transmitter being coupled to said outer wall of said housing, said transmitter being electrically coupled to said control circuit, said transmitter being in wireless electrical communication with the personal electronic device when the personal electronic device is positioned in said housing, said transmitter broadcasting an electrical charge to the personal electronic device for charging the personal electronic device.
